(19) United States
(12) Patent Application Publication
(10) Pub. No.: US 2026/0068219 A1
(43) Pub. Date: Mar. 5, 2026

(54) SEMICONDUCTOR DEVICE AND MANUFACTURING METHOD

(71) Applicants: Kabushiki Kaisha Toshiba, Tokyo (JP); Toshiba Electronic Devices & Storage Corporation, Tokyo (JP)

(72) Inventors: Shunsuke KAMIYA, Komatsu Ishikawa (JP); Kazuki MATSUO, Nonoichi Ishikawa (JP)

(21) Appl. No.: 19/067,680

(22) Filed: Feb. 28, 2025

(30) Foreign Application Priority Data
Aug. 30, 2024 (JP) 2024-148168

(51) Int. Cl. H10D 30/66; H10D 30/01; H10D 62/10; H10D 62/13; H10D 64/00; H10D 64/27; H10D 64/68

(52) U.S. Cl. CPC H10D 30/668; H10D 30/0297; H10D 30/665; H10D 62/102; H10D 62/153; H10D 62/157; H10D 64/117; H10D 64/513; H10D 64/516; H10D 64/518; H10D 64/685; H10D 64/693

(57) ABSTRACT

According to one embodiment, a semiconductor device has a first semiconductor layer of a first conductivity type between first and second electrodes. A second semiconductor layer of a second conductivity type is on the first semiconductor layer. A field plate electrode extends from the first semiconductor layer to the second semiconductor layer. A field plate insulating layer is between the first semiconductor layer and the field plate electrode. A gate electrode has a first side facing the second semiconductor layer, a second side facing the field plate electrode, and having an apex portion extending into the field plate insulating layer at a position spaced from the first side and the second side. A first insulating layer is between the field plate electrode and the gate electrode, and a second insulating layer is between the gate electrode and the second electrode.

### CROSS-REFERENCE TO RELATED APPLICATION(S)

This application is based upon and claims the benefit of priority from Japanese Patent Application No. 2024-148168, filed Aug. 30, 2024, the entire contents of which are incorporated herein by reference.

### FIELD

Embodiments described herein relate generally to a semiconductor device.

### BACKGROUND

A semiconductor device, such as a metal-oxide-semiconductor field-effect transistor (MOSFET), can be used as a switching element. During the semiconductor device manufacturing process, a process of etching an insulating layer enclosing a field plate may determine a form of a gate electrode formed of polysilicon.

If the shape of the gate electrode is sharply angled at the interface between the gate electrode and a thin gate insulating layer, then a local electric field concentration is likely to occur at this location, possibly leading to destruction of the gate insulating layer.

### BRIEF DESCRIPTION OF THE DRAWINGS

FIG. 1 is a schematic cross-sectional view of a semiconductor device 100 according to a first embodiment.

FIG. 2 is an enlarged view showing a portion A enclosed by broken lines in FIG. 1.

FIGS. 3-8 depict aspects of a process of manufacturing a semiconductor device 100 according to the first embodiment.

FIG. 9 is an enlarged view showing a portion B enclosed by broken lines in FIG. 8.

FIGS. 10-16 depict additional aspects of a process of manufacturing a semiconductor device 100 according to the first embodiment. FIG. 17 is a schematic cross-sectional of a semiconductor device 200 according to a first comparative example.

FIG. 18 is an enlarged view showing a portion C enclosed by broken lines in FIG. 17.

FIG. 19 is a schematic cross-sectional view depicting an aspect of a process of manufacturing a semiconductor device 200 according to the first comparative example.

### DETAILED DESCRIPTION

Embodiments provide a semiconductor device for which a decrease in breakdown voltage may be prevented by controlling a shape of a gate electrode.

In general, according to one embodiment, a semiconductor device includes a first semiconductor layer of a first conductivity type between a first electrode and a second electrode in a first direction and electrically connected to the first electrode. A second semiconductor layer of a second conductivity type is on the first semiconductor layer. The second semiconductor layer is between the first semiconductor layer and the second electrode in the first direction. A third semiconductor layer of the first conductivity type is between the second semiconductor layer and the second electrode in the first direction and electrically connected to the second electrode. A field plate electrode extends in the first direction from the first semiconductor layer to the second semiconductor layer. A field plate insulating layer is between the first semiconductor layer and the field plate electrode. A gate electrode has a first side facing towards the second semiconductor layer, a second side facing towards the field plate electrode, and a bottom face contacting the field plate insulating layer. The bottom face has an apex portion that extends into the field plate insulating layer at a position spaced from the first side and the second side. A first interlayer insulating layer is between the field plate electrode and the gate electrode. A second interlayer insulating layer is between the gate electrode and the second electrode.

Hereafter, certain example embodiments of the present disclosure will be described while referring to the drawings. In the description, the same reference symbols will be allotted to those aspects or elements depicted in different drawings.

These example embodiments do not limit the present disclosure, nor do the depicted dimensions and dimensional ratios in the drawings. In the following described examples, a first conductivity type is generally considered to be an n-type while a second conductivity type is considered to be a p-type, but this is not limiting. In other examples, the first conductivity type may be a p-type and the second conductivity type an n-type.

Also, in the following description, the notations n⁺, n, n⁻ and p⁺, p, p⁻ represent a relative impurity concentration of each conductivity type. That is, n′ indicates that an n-type impurity concentration is relatively higher than n, and n⁻ indicates that the n-type impurity concentration is relatively lower than n. Similarly, p⁺ indicates that a p-type impurity concentration is relatively higher than p, and p⁻ indicates that the p-type impurity concentration is relatively lower than p. Also, an n⁺-type and an n⁻-type region or material may each be referred to simply as an n-type region or material, while a p⁺-type and a p⁻-type region or material may similarly be expressed simply as a p-type region or material.

### First Embodiment

### Semiconductor Device 100 Structure

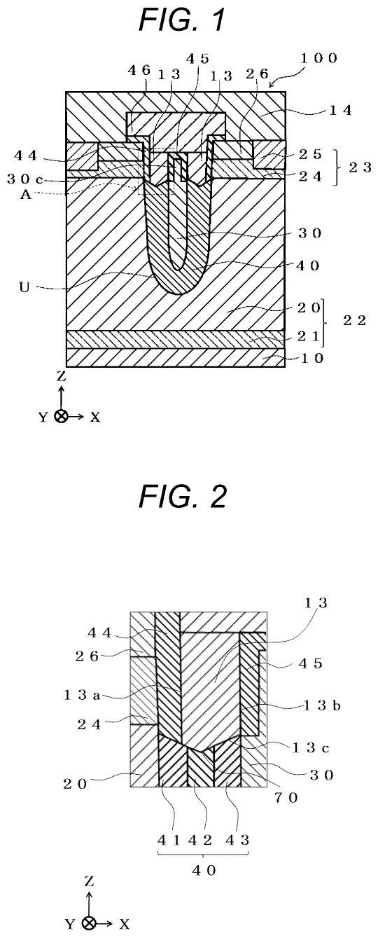

A structure of a semiconductor device 100 according to a first embodiment will be described with reference to FIGS. 1 and 2. FIG. 1 is a schematic cross-sectional view of the semiconductor device 100 according to the first embodiment. FIG. 2 shows a portion A enclosed by broken lines in FIG. 1.

The semiconductor device 100 is, for example, a MOSFET such as vertical transistor semiconductor device. In this example, semiconductor device 100 has a drain electrode 10, a gate electrode 13, a source electrode 14, an n-type semiconductor region 22, a p-type semiconductor region 23, an n-type source layer 26, a field plate electrode 30, and a field plate insulating layer 40.

The drain electrode 10 is one example of a first electrode, and the source electrode 14 is one example of a second electrode.

The direction going from the drain electrode 10 toward the n-type semiconductor region 22 is a Z direction (a first direction). Also, a direction perpendicular to the Z direction is an X direction (a second direction), and a direction perpendicular to the X direction and the Z direction is a Y direction (a third direction). The semiconductor device 100 shown in FIG. 1 is a cross-sectional view in an X-Z plane. Herein, for the sake of descriptive convenience, the direction going from the drain electrode 10 toward the n-type semiconductor region 22 may be called “up” or “upward,” and the opposite direction “down” or “downward.”

The semiconductor device 100 in FIG. 1 includes an n⁻ type drift layer 20 and a p-type base layer 24. The p-type base layer 24 is provided on the n-type drift layer 20 in the Z direction.

The n-type source layer 26 and a p-type contact layer 25 are arranged in parallel on the p-type base layer 24. An n⁻ type drain layer 21 is provided in a −Z direction from the n-type drift layer 20.

The n-type semiconductor region 22 comprises the n⁻ type drift layer 20 and the n-type drain layer 21. The p-type semiconductor region 23 comprises the p-type base layer 24 and the p-type contact layer 25. Incorporation of the n-type drain layer 21 and the p-type contact layer 25 is not essential for all possible examples. The n-type semiconductor region 22 may include just the n-type drift layer 20 only. The p-type semiconductor region 23 may include just the p-type base layer 24 only.

The n-type drift layer 20 is one example of a first semiconductor layer of a first conductivity type. The p-type base layer 24 is one example of a second semiconductor layer of a second conductivity type. The n-type source layer 26 is one example of a third semiconductor layer of the first conductivity type. The n-type drain layer 21 is one example of a fourth semiconductor layer of the first conductivity type. The p-type contact layer 25 is one example of a fifth semiconductor layer of the second conductivity type.

The n-type impurity concentration of the n-type drain layer 21 is higher than an n-type impurity concentration of the n-type drift layer 20. The p-type impurity concentration of the p-type contact layer 25 is higher than a p-type impurity concentration of the p-type base layer 24.

In this example, the n-type drain layer 21, the n⁻ type drift layer 20, the p-type base layer 24, the n-type source layer 26, and the p-type contact layer 25 comprise silicon (Si) or silicon carbide (SiC) as a semiconductor material. When silicon is used as a semiconductor material, arsenic (As), phosphorus (P), or antimony (Sb) can be used as an n-type impurity and boron (B) can be used as a p-type impurity.

The semiconductor device 100 has a trench U that passes from an upper face of the n-type source layer 26 through the n-type source layer 26 and the p-type base layer 24 to reach inside the n-type drift layer 20. The field plate electrode 30, which extends in a direction from the p-type base layer 24 toward the n-type drain layer 21, is provided in an interior of the trench U. The field plate electrode 30 is enclosed by the n-type drift layer 20 with the field plate insulating layer 40 therebetween.

The gate electrode 13 is provided on a Z direction upper end of the field plate insulating layer 40 in the interior of the trench U. The gate electrode 13 faces the p-type base layer 24 in the X direction. A gate insulating layer 44 is provided between the gate electrode 13 and the p-type base layer 24. A thickness of the gate insulating layer 44 is less than that of the field plate insulating layer 40.

Also, a field plate electrode upper end portion 30c is provided on an upper end in the Z direction of the field plate electrode 30. The field plate electrode upper end portion 30c extends between two gate electrodes 13 spaced from each other in the X direction. That is, a gate electrode 13 (or portion thereof) is positioned between the field plate electrode 30 and the p-type base layer 24. A first interlayer insulating layer 45 is provided between the field plate electrode upper end portion 30c and the gate electrode 13.

A second interlayer insulating layer 46 is provided on the gate electrode 13 and the field plate electrode upper end portion 30c. The source electrode 14 is provided on the second interlayer insulating layer 46, the n-type source layer 26, and the p-type contact layer 25. The source electrode 14 is electrically connected to the n-type source layer 26 and to the p-type base layer 24 (via the p-type contact layer 25). The drain electrode 10 is provided on a back side face of the n-type drain layer 21 in the −Z direction from the n-type drift layer 20.

In the present example, the drain electrode 10 and the source electrode 14 comprise a metal such as aluminum (Al) or copper (Cu). The field plate electrode 30 and the gate electrode 13 are, for example, polysilicon, and include phosphorus or boron as a conductive impurity (dopant). The field plate insulating layer 40, the gate insulating layer 44, the first interlayer insulating layer 45, and the second interlayer insulating layer 46 are insulating films comprising, for example, silicon.

The semiconductor device 100 is configured such that a drain current flowing between the drain electrode 10 and the source electrode 14 can be controlled by the gate electrode 13. The field plate electrode 30 is connected to the source electrode 14 in an end portion or the otherwise. The field plate electrode 30 is thus electrically connected to the source electrode 14. Further, the field plate electrode 30 controls an electric field in the n-type drift layer 20, which is positioned farther in the −Z direction than the gate electrode 13, and functions to cause a drift-source breakdown voltage to increase.

A gate pad to be connected to an external power supply (or to a gate controller) is provided separated from the aforementioned element regions in another portion of the semiconductor device 100. Gate wiring is electrically connected to the gate pad and provided on a surface of the semiconductor device 100. The gate wiring is connected to the gate electrode 13, which is led out onto the surface of the semiconductor device 100.

Next, a structure of the gate electrode 13 will be described using FIG. 2, which shows the portion A enclosed by broken lines in FIG. 1.

In FIG. 2, the gate electrode 13 has a side wall 13a, a side wall 13b, and a lower face 13c. The side wall 13a opposes the p-type base layer 24 across the gate insulating layer 44, and the side wall 13b opposes the field plate electrode 30 across the first interlayer insulating layer 45. The lower face 13c is connected to the side wall 13a and the side wall 13b and contacts the field plate insulating layer 40 in the −Z direction. Also, the semiconductor device 100 according to the present embodiment is such that an apex 70 (oriented towards the −Z direction) is formed near a center region of the lower face 13c. The apex 70 is a lowermost point (in the −Z direction) of the lower face 13c.

Next, certain characteristics of a structure of the field plate insulating layer 40 will be described using FIG. 2.

The field plate insulating layer 40 has a three-layer structure comprising a first insulating layer 41, which is in contact with the n-type drift layer 20, a second insulating layer 42, which is provided between the first insulating layer 41 and the field plate electrode 30, and a third insulating layer 43, which is provided between the second insulating layer 42 and the field plate electrode 30. The second insulating layer 42 is positioned between the first insulating layer 41 and the third insulating layer 43.

Also, in general, the electric field changes abruptly at the sharp point of apex 70, meaning that an electric field concentration occurs easily. Because of this, the apex 70 is preferably disposed near a middle point along the X direction of the field plate insulating layer 40. That is, apex 70 extends into the field plate insulating layer at a position spaced from the side wall 13a and the side wall 13b. For example, if the apex 70 were formed in a position in contact with the side wall 13a, the electric field concentration is liable to occur in the vicinity of a lower end of the gate insulating layer 44, which has a small X direction thickness. In order not to cause an electric field concentration to occur in a place in which an insulating layer is thin in this way, the apex 70 may, for example, be formed to be in contact with the second insulating layer 42.

### Semiconductor Device 100 Manufacturing Method

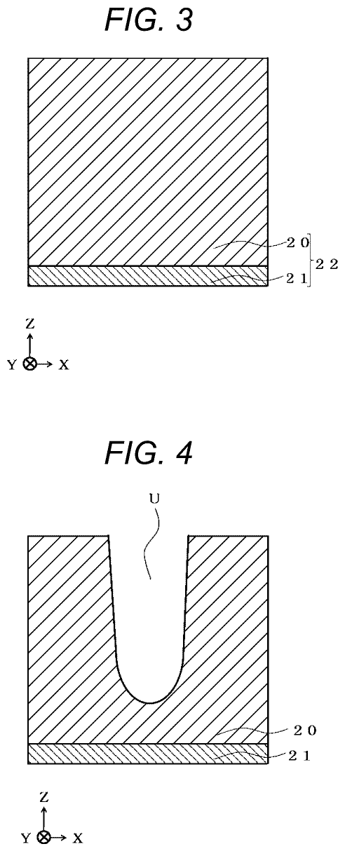

Next, referring to FIGS. 3 to 16, a process of manufacturing the semiconductor device 100 according to an embodiment will be described. FIGS. 3 to 16 are schematic cross-sectional views relating to certain aspects of a semiconductor device manufacturing process according to an embodiment.

Firstly, as represented in FIG. 3, the n-type drift layer 20 is formed on the n-type drain layer 21. At this time, the n-type impurity concentration of the n-type drain layer 21 is higher than that of the n-type drift layer 20. The n-type impurity concentration of the n-type drain layer 21 is, for example, in a range of 1× 10¹⁷ cm⁻³ to 5×10¹⁷ cm⁻³.

Next, as shown in FIG. 4, trenches U are formed in the n-type drift layer 20 from an upper face of the n-type drift layer 20 using RIE (reactive ion etching). In general, multiple trenches U will be formed in a device, but figures depict only a single representative trench U for convenience and clarity of description.

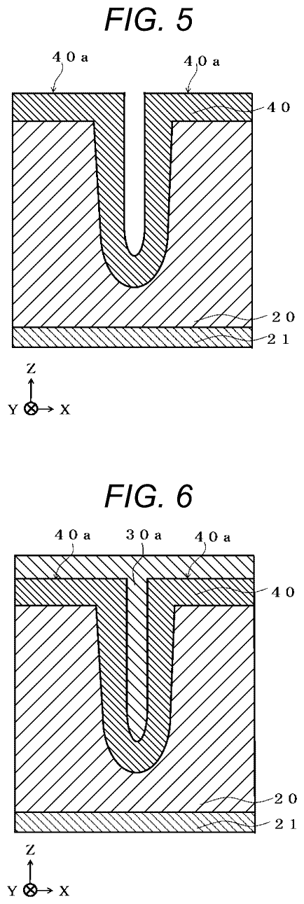

Next, as shown in FIG. 5, the field plate insulating layer 40 is formed by the first insulating layer 41, the second insulating layer 42, and the third insulating layer 43 being formed in this order on the upper face of the n-type drift layer 20 and on a whole inner face, including a side face and a bottom face, of the trench U. The field plate insulating layer 40 is configured with three layers such that insulating films whose etching speeds during a wet etching differ are in contact.

Specifically, the second insulating layer 42 is configured with an insulating film whose etching speed during wet etching is greater than that of the first insulating layer 41 and the third insulating layer 43.

For example, a silicon nitride (SiN) film, a dual-frequency silicon nitride (D-SiN) film, a semi-insulated silicon nitride (SInSiN) film, a silicon oxynitride (SiON) film, or the like, may be used in the first insulating layer 41 and the third insulating layer 43 as an insulating film whose etching speed is slow. A D-SiN film is a SiN film formed by plasma CVD in which two frequencies of plasma are used.

A silicon nitride film such as SiN, D-SiN, and SInSiN has a dense structure in comparison with a silicon oxide film, which can be deposited using a general chemical vapor deposition (CVD) method. Generally, such dense structure films as mentioned are characterized by an etching speed during wet etching that is slow.

That is, in an example, the second insulating layer 42 is a silicon oxide film, and the first insulating layer 41 and the third insulating layer 43 are silicon nitride films. In some examples, a silicon oxide film including phosphorus and boron (Boron Phosphorus Silicon Glass: BPSG) may be used as an insulating film whose wet etching speed is slow.

A formation order of the aforementioned insulating films may be such that the second insulating layer 42 is formed after the first insulating layer 41 is formed, and the third insulating layer 43 is formed last.

The first to third insulating layers 41 to 43 are not limited to the heretofore described examples, it is sufficient that the first to third insulating layers 41 to 43 are formed of films having characteristics that the etching speeds during wet etching of the first insulating layer 41 and the third insulating layer 43 are slower than the etching speed of the second insulating layer 42.

Next, the field plate electrode 30 is formed. As shown in FIG. 6, the conductive layer 30a is formed using CVD on a first face 40a to fill the trench U. The conductive layer 30a is, for example, polysilicon, and includes, for example, phosphorus or boron as a conductive impurity.

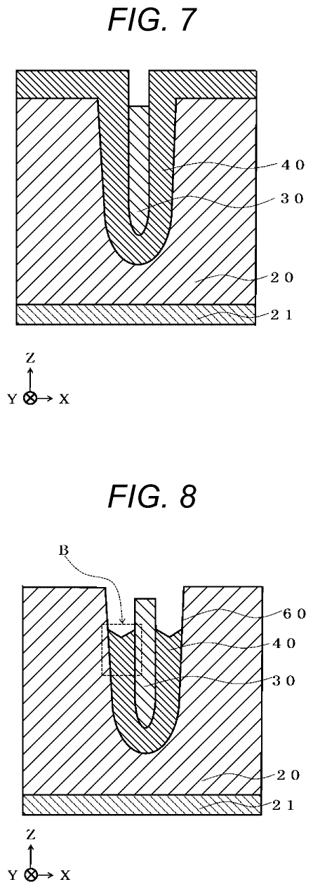

Next, as shown in FIG. 7, portions of the conductive layer 30a are removed using RIE in such a way that a portion remains inside the trench U, from which the field plate electrode 30 is formed.

Continuing in the process, the field plate insulating layer 40 is caused to recede in the −Z direction from the upper face of the n-type drift layer 20 by selective etching using wet etching, thereby exposing the upper face of the n-type drift layer 20. By continuing the etching, a groove portion 60 is formed in the upper end of the field plate insulating layer 40 inside the trench U, as shown in FIG. 8. The groove portion 60 is formed in the Z direction upper end of the field plate insulating layer 40. The groove portion 60 is provided in the interior of the trench U, and is between, and opposes, the field plate electrode 30 and the n-type drift layer 20 in the X direction.

In the present example, the groove portion 60 of the desired form is formed by utilizing the difference in wet etching speeds of the first to third insulating layers (41 to 43) forming the field plate insulating layer 40. That is, the field plate insulating layer 40 has three layers, and the wet etching speed of the second insulating layer 42 is greater than that of the first insulating layer 41 and the third insulating layer 43. Because of this, etching of the second insulating layer 42 proceeds more quickly.

Also, by using a wet etching solution that has selectivity with respect to polysilicon, the field plate insulating layer 40 can be selectively etched without significantly etching the field plate electrode 30. Furthermore, an etching solution is selected such that the etching speed of the second insulating layer 42 is greater than that of the first insulating layer 41 and the third insulating layer 43. When the second insulating layer 42 is a silicon oxide film and the first insulating layer 41 and the third insulating layer 43 are silicon nitride films, an etching solution including hydrofluoric acid or the like can be used since hydrofluoric acid has a high etching speed with respect to silicon oxide films. For example, when the hydrofluoric (HF) acid concentration is 37% in an etchant solution and an etching temperature is 65 degrees, the silicon oxide film etching speed is approximately 45 nm/sec, while the silicon nitride film etching speed is approximately 3 nm/sec. Similarly, an etching speed ratio can be adjusted using HF concentration and etch temperature as variables. When the first insulating layer 41 and the third insulating layer 43 are SiON films, etching speed of such films can be reduced by raising a nitrogen ratio therein.

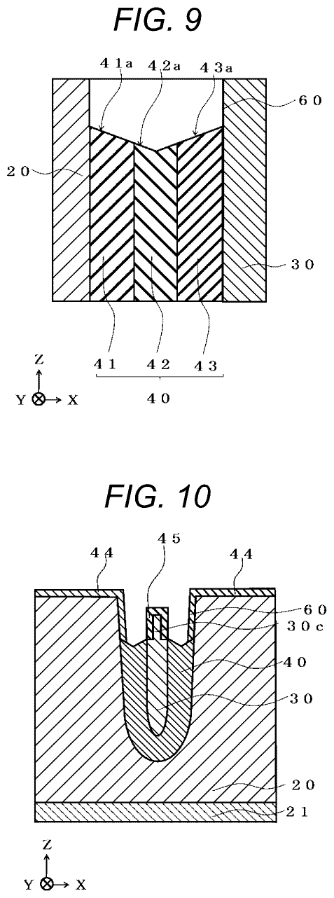

FIG. 9 shows a portion B enclosed by broken lines in FIG. 8. As shown in FIG. 9, the groove portion 60, in which the gate electrode 13 is to be formed, is formed in the upper end of the field plate insulating layer 40 by a wet etching of the field plate insulating layer 40. The groove portion 60 comprises an upper face 41a of the first insulating layer 41, an upper face 42a of the second insulating layer 42, and an upper face 43a of the third insulating layer 43.

According to FIG. 9, the upper face 42a of the second insulating layer 42 is positioned farther in the −Z direction than the upper face 41a of the first insulating layer 41 and the upper face 43a of the third insulating layer 43. In this example, the n-type drift layer 20 is exposed at the side wall of the trench U.

Next, the upper face of the n-type drift layer 20, a side face portion of the n-type drift layer 20 that is exposed at the side wall of the trench U, and the upper face and the side face of the field plate electrode 30 are oxidized in a thermal oxidizing process using heating. As shown in FIG. 10, the gate insulating layer 44, which covers the upper face of the n-type drift layer 20 and the side face of the n-type drift layer 20 exposed in the side wall of the trench U, and the first interlayer insulating layer 45, which covers an upper portion of the field plate electrode 30, are newly formed. At this time, oxidization of the upper face of the field plate insulating layer 40 also proceeds.

When the first interlayer insulating layer 45 is formed, an upper end portion of the field plate electrode 30 is oxidized, because of which just the narrowed field plate electrode upper end portion 30c remains.

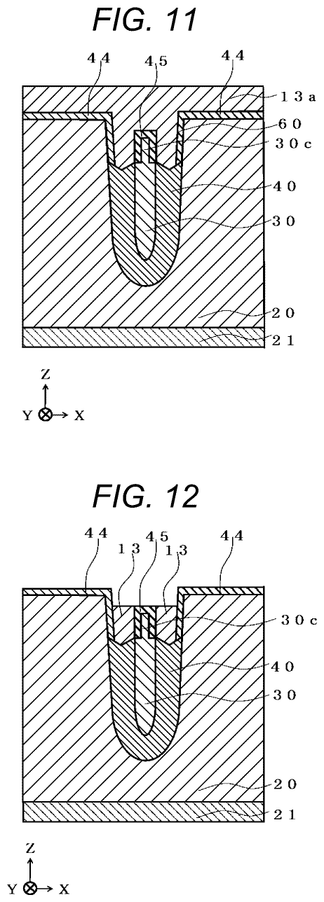

Next, as shown in FIG. 11, a conductive layer 13a is formed using CVD to form a portion above the n-type drift layer 20 and fill the groove portion 60 of the trench U. The conductive layer 13a comprises polysilicon and a conductive impurity such as phosphorus or boron.

Continuing, as shown in FIG. 12, the gate electrode 13 is formed on the field plate insulating layer 40 by etching the conductive layer 13a. At this time, the conductive layer 13a is caused to recede by etching until the first interlayer insulating layer 45 is exposed. The gate electrode 13 is thus formed between the field plate electrode upper end portion 30c and the n-type drift layer 20. A pair of gate electrodes 13 are arranged in parallel so as to sandwich the field plate electrode upper end portion 30c therebetween.

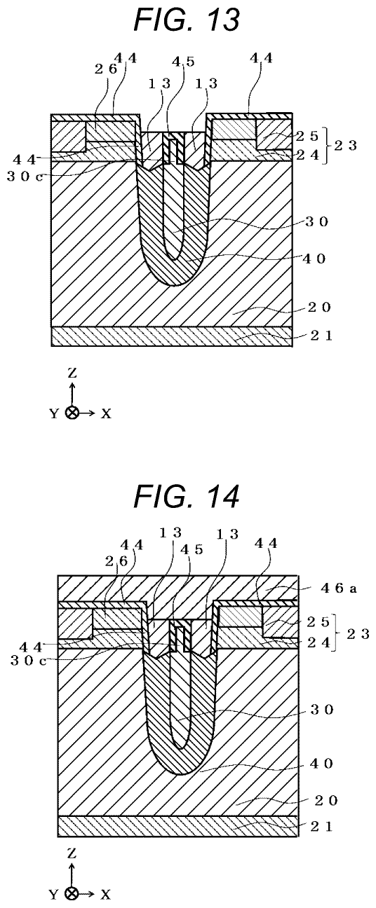

Next, as shown in FIG. 13, the p-type base layer 24 is formed in an upper portion of the n-type drift layer 20. For example, an ion implantation of a p-type impurity into the upper face of the n-type drift layer 20 is carried out, and implanted ions are activated by heat treatment. The p-type impurity diffuses to a predetermined depth during the heat treatment process.

Continuing, the n-type source layer 26 is formed in an upper portion of the p-type base layer 24. The n-type source layer 26 opposes an upper end of the gate electrode 13 in the X direction across the gate insulating layer 44. The n-type source layer 26 is formed by, for example, an ion implantation of an n⁻ type impurity being selectively carried out from an upper face of the p-type base layer 24, and activated by heat treatment. A −Z direction lower end of the n-type source layer 26 may coincide with the upper end of the gate electrode 13 in the X direction.

Next, the p-type contact layer 25 is formed in an upper portion of the p-type base layer 24. The p-type contact layer 25 is formed by, for example, an ion implantation of a p⁻ type impurity being selectively carried out from the upper face of the p-type base layer 24, and activated by heat treatment being implemented. The p-type contact layer 25 is arranged in parallel with the n-type source layer 26 in the X direction.

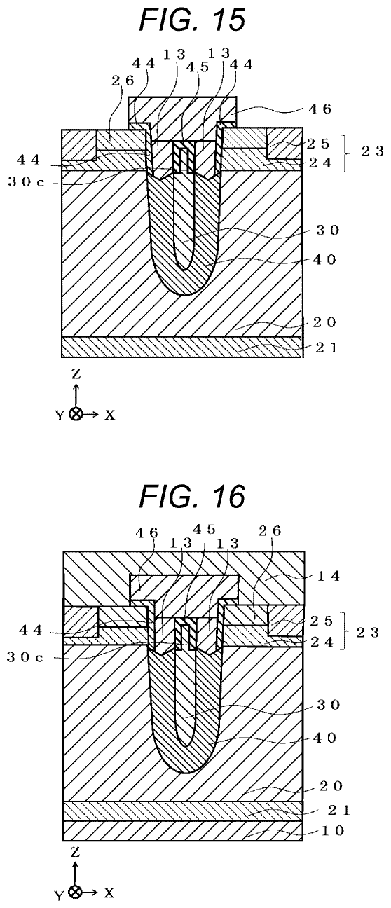

Next, as shown in FIG. 14, an insulating layer 46a that covers the trench U is formed on the gate electrode 13, the field plate electrode 30, the n-type source layer 26, and the p⁻ type base layer 24, after which, as shown in FIG. 15, a portion of the insulating layer 46a on the n-type source layer 26, the p-type base layer 24, and the gate insulating layer 44 is removed, thereby forming the second interlayer insulating layer 46.

Continuing, as shown in FIG. 16, the source electrode 14 is formed above the n-type source layer 26 and the p-type contact layer 25.

Furthermore, the drain electrode 10 is formed below the n-type drain layer 21. The semiconductor device 100 represented in FIG. 1 has thus been manufactured using the described processes.

### First Comparative Example

Next, FIG. 17 is a schematic cross-sectional view of a semiconductor device 200 according to a first comparative example.

The semiconductor device 200 is such that a cross-sectional form of a gate electrode 15 differs in comparison with that of the gate electrode 13 of the semiconductor device 100 according to the first embodiment. The field plate insulating layer 48 is configured with only a single layer, though the field plate insulating layer 48 could be formed of two layers.

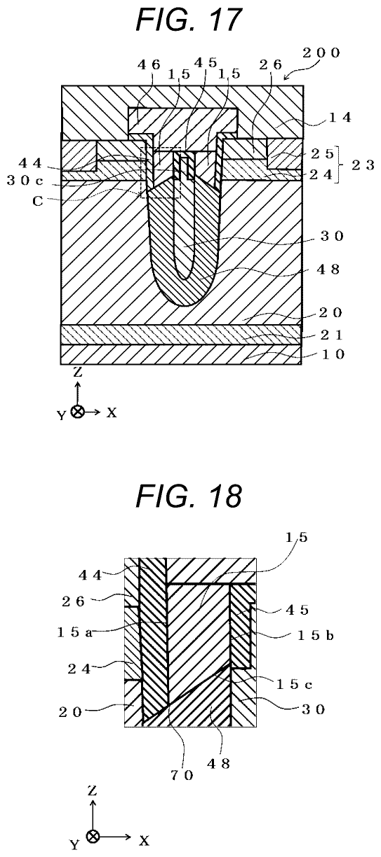

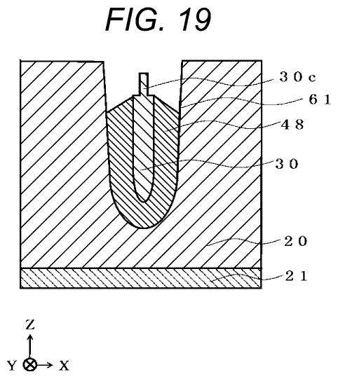

The structure of the gate electrode 15 of the semiconductor device 200 will be described using FIG. 18, in which a portion C enclosed by broken lines in FIG. 17 is enlarged.

The gate electrode 15 of the semiconductor device 200 has a side wall 15b, which is in contact with the field plate electrode 30 across the first interlayer insulating layer 45, and a side wall 15a, which is in contact with one portion of the n⁻ type drift layer 20, the p-type base layer 24, and the n-type source layer 26 across the gate insulating layer 44.

The semiconductor device 200 is such that the −Z direction apex 70 on a lower face 15c of the gate electrode 15 is positioned adjacent the side wall 15a.

A cross-sectional structure of a gate electrode 15 of the semiconductor device 200 shown in FIG. 18 is present, for example, in a portion at which the field plate electrode 30 is led out onto a surface of the drift layer 20 in a boundary region between an element region and an end region. When etching the field plate electrode 30 using RIE, a portion of the field plate electrode 30 led out onto the surface of the drift layer 20 is protected by a resist or the like in the end region. It is supposed that a residue of a resist applied in the end region when etching the field plate insulating layer 48 using RIE in this state has an effect.

In the first comparative example, the field plate insulating layer 48 is formed of one layer or two layers. The field plate insulating layer 48 may comprise any of the first to third insulating layer materials described in the first embodiment.

FIG. 19 is a cross-sectional schematic view in the first comparative example after the field plate insulating layer 48 is caused to recede in the −Z direction by wet etching. As shown in FIG. 19, a side wall portion of the trench U at which the n-type drift layer 20 is exposed is deeper in the −Z direction than the side wall opposing in the X direction at which the field plate electrode 30 is exposed. As previously mentioned, this may be an effect of a residue of applied resist used in etching by RIE. That is, a process of etching of the field plate insulating layer 48 along a side wall of the field plate electrode 30 that is a vicinity of a resist residue is slow, and etching of the field plate insulating layer 48 along a side wall of the trench U proceeds more quickly. Because of this, a difference occurs in a cross-sectional form of the gate electrode that fills the groove portion 61.

Thus, the semiconductor device 200 differs from the first embodiment in being of a structure such that the sharp apex 70 of the gate electrode 15 is formed along the side wall 15a, as shown in FIG. 18. This kind of structure is such that an electric field concentration is caused to occur in a vicinity of an extremely thin insulating layer like the gate insulating layer 44, so a sufficient breakdown voltage cannot be secured, and a risk of product destruction increases.

### First Embodiment Advantages

According to the first embodiment, etching of the field plate insulating layer 40 proceeds more easily (quickly) near in the X direction thickness midpoint (center region). Because of this, the structure is such that the sharp apex 70 does not like form at the side wall 13a or the side wall 13b of the gate electrode 13.

Also, the semiconductor device 100 according to the first embodiment is such that when the sharp apex 70 is formed on the lower end of the gate electrode 13 it is in a portion near the middle (center) of the field plate insulating layer 40, thus, the thickness of a field plate insulating layer 40 between the apex 70 of the gate electrode 13, at which electric field concentration occurs, and the n-type drift layer is greater than that in the first comparative example

As heretofore described, the semiconductor device 100 according to the first embodiment is such that the position of the apex 70, in which an electric field concentration is liable to occur, can be controlled, and a decrease in breakdown voltage can be prevented.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first semiconductor layer of a first conductivity type between a first electrode and a second electrode in a first direction and electrically connected to the first electrode;
a second semiconductor layer of a second conductivity type on the first semiconductor layer, the second semiconductor layer being between the first semiconductor layer and the second electrode in the first direction;
a third semiconductor layer of the first conductivity type between the second semiconductor layer and the second electrode in the first direction and electrically connected to the second electrode;
a field plate electrode extending in the first direction from the first semiconductor layer to the second semiconductor layer;
a field plate insulating layer between the first semiconductor layer and the field plate electrode;
a gate electrode having a first side facing towards the second semiconductor layer, a second side facing towards the field plate electrode, and a bottom face contacting the field plate insulating layer and having an apex portion extending into the field plate insulating layer at a position spaced from the first side and the second side;
a first interlayer insulating layer between the field plate electrode and the gate electrode; and
a second interlayer insulating layer between the gate electrode and the second electrode.

2. The semiconductor device according to claim 1, wherein the field plate insulating layer comprises:
a first insulating layer contacting the first semiconductor layer,
a second insulating layer between the first insulating layer and the field plate electrode, and
a third insulating layer between the second insulating layer and the field plate electrode.

3. The semiconductor device according to claim 2, wherein the apex portion has its lowermost point contacting the second insulating layer.

4. The semiconductor device according to claim 2, wherein
the first and the third insulating layers are silicon nitride films, and
the second insulating layer is a silicon oxide film.

5. The semiconductor device according to claim 2, wherein the first and the third insulating layers have an etching rate that is lower than an etching rate of the second insulating layer in a wet etching process.

6. The semiconductor device according to claim 1, further comprising:
a fourth semiconductor layer of the first conductivity type between the first semiconductor layer and the first electrode in the first direction, wherein
an impurity concentration of the first conductivity type is higher in the fourth semiconductor layer than in the first semiconductor layer.

7. The semiconductor device according to claim 6, further comprising:
a fifth semiconductor layer of the second conductivity type between the second semiconductor layer and the second electrode in the first direction, wherein
an impurity concentration of the second conductivity type in the fifth semiconductor layer is higher than in the second semiconductor layer.

8. The semiconductor device according to claim 1, further comprising:
a fourth semiconductor layer of the second conductivity type between the second semiconductor layer and the second electrode in the first direction, wherein
an impurity concentration of the second conductivity type in the fourth semiconductor layer is higher than in the second semiconductor layer.

9. A vertical transistor semiconductor device, comprising:
a first semiconductor layer of a first conductivity type between a first electrode and a second electrode in a first direction, the first semiconductor layer being electrically connected to the first electrode;
a second semiconductor layer of a second conductivity type, the second semiconductor layer being between the first semiconductor layer and the second electrode in the first direction;
a trench extending in the first direction through the second semiconductor layer into the first semiconductor layer;
a field plate electrode in the trench, the field plate electrode having an upper portion and a lower portion;
a field plate insulating film in the trench, the field plate insulating film being between the field plate electrode and the first semiconductor layer;
a gate electrode in the trench between the field plate electrode and a sidewall of the trench;
a first insulating layer between the upper portion of the field plate electrode and the gate electrode; and
a second insulating layer between the gate electrode and the second semiconductor layer, wherein
a bottom surface of the gate electrode contacts the field plate insulating film,
a first sidewall of the gate electrode contacts the first insulating layer,
a second sidewall of the gate electrode contacts the second insulating layer, and
a lowermost point of the bottom surface of the gate electrode in the first direction into the field plate insulating film is offset from both the first sidewall and the second sidewall of the gate electrode.

10. The vertical transistor semiconductor device according to claim 9, wherein
the field plate insulating film comprises at least three layers, and
the lowermost point of the bottom surface of the gate electrode is an interior one of the at least three layers.

11. The vertical transistor semiconductor device according to claim 10, further comprising:
a third semiconductor layer of the first conductivity type between the second semiconductor layer and the second electrode in the first direction.

12. The vertical transistor semiconductor device according to claim 10, wherein the interior one of the at least three layers is a silicon oxide film.

13. The vertical transistor semiconductor device according to claim 12, wherein
an outermost one of the at least three layers that contacts the first semiconductor layer is a silicon nitride layer.

14. The vertical transistor semiconductor device according to claim 12, wherein
an innermost one of the at least three layers that contacts the field plate electrode is a silicon nitride layer.

15. The vertical transistor semiconductor device according to claim 10, further comprising:
a fourth semiconductor layer of the second conductivity type between the second semiconductor layer and the second electrode in the first direction, wherein
an impurity concentration of the second conductivity type in the fourth semiconductor layer is higher than in the second semiconductor layer.

16. The vertical transistor semiconductor device according to claim 9, wherein a maximum width of the upper portion of the field plate electrode in a second direction intersecting the first direction is less than a maximum width of the lower portion of the field plate electrode in the second direction.

17. The vertical transistor semiconductor device according to claim 9, further comprising:
an interlayer insulating film between the gate electrode and the second electrode in the first direction.

18. A semiconductor device manufacturing method, comprising:
forming a trench in a first semiconductor layer of a first conductivity type;
forming a first insulating layer on a side wall of the trench, the first insulating layer being a first material;
forming a second insulating layer on the side wall of the trench with the first insulating layer therebetween, the second insulating layer being a second material;
forming a third insulating layer on the sidewall of the trench with the second insulating layer therebetween, the third insulating layer being a third material;
forming a field plate electrode in the trench contacting the third insulating layer;
performing a wet etching process to cause an upper end of each of the first insulating layer, the second insulating layer, and the third insulating layer to recede from an upper surface the first semiconductor layer into the first semiconductor layer, thereby causing a portion of the side wall of the trench and a upper end portion of the field plate electrode to be exposed;
oxidizing the exposed portion of the side wall of the trench and the exposed upper end portion of the field plate electrode; and
forming a gate electrode between the trench sidewall and the oxidized upper end portion of the field plated on the upper ends of each of the first insulating layer, the second insulating layer, and the third insulating layer, wherein
the first material has a slower etch rate in the wet etch process than the second material.

19. The semiconductor device manufacturing method according to claim 18, wherein
the first and the third insulating layers are silicon nitride films, and
the second insulating layer is a silicon oxide film.

20. The semiconductor device manufacturing method according to claim 18, wherein an apex portion of the gate electrode is in direct contact with the second insulating layer.
